(19) United States
(12) Patent Application Publication
(10) Pub. No.: US 2015/0116242 A1
(43) Pub. Date: Apr. 30, 2015

(54) TOUCH SENSOR

(71) Applicant: SAMSUNG ELECTRO-MECHANICS CO., LTD., Suwon-Si (KR)

(72) Inventors: Beom Seok OH, Suwon-Si (KR); Tae Kyung Lee, Suwon-Si (KR); Ho Joo Lee, Suwon-Si (KR)

(73) Assignee: SAMSUNG ELECTRO-MECHANICS CO., LTD., Suwon-Si (KR)

(21) Appl. No.: 14/512,241

(22) Filed: Oct. 10, 2014

(30) Foreign Application Priority Data
Oct. 29, 2013 (KR) 10-2013-0129390

(51) Int. Cl. G06F 3/041; H05K 3/24

(52) U.S. Cl. CPC G06F 3/041; H05K 3/245; G06F 2203/04103; G06F 2203/04107
USPC 345/173; 29/846

(57) ABSTRACT

Disclosed herein is a touch sensor. The touch sensor includes: a window substrate; a base substrate having one surface formed so as to be bonded to the window substrate and the other surface having a first electrode pattern formed thereon; a bezel formed along an edge of the base substrate; an insulating layer applying the electrode pattern while filling between the bezel and the bezel; and a second electrode pattern formed on the insulating layer.

### CROSS REFERENCE TO RELATED APPLICATION

This application claims the benefit of Korean Patent Application No. 10-2013-0129390, filed on Oct. 29, 2013, entitled “Touch Sensor”, which is hereby incorporated by reference in its entirety into this application.

### BACKGROUND OF THE INVENTION

1. Technical Field

The present invention relates to a touch sensor.

2. Description of the Related Art

In accordance with a development of a computer using a digital technology, devices assisting computers have also been developed, and personal computers, portable transmitters and other personal information processors execute text and graphic processing using a variety of input devices such as a keyboard and a mouse.

In accordance with the rapid advancement of an information-oriented society, the use of computers has gradually been widened; however, it is difficult to efficiently operate products using only the keyboard and the mouse currently serving as an input device. Therefore, the necessity for a device that is simple, has minimum malfunction, and is capable of easily inputting information has increased.

In addition, techniques for input devices have progressed toward techniques related to high reliability, durability, innovation, designing and processing beyond a level of satisfying general functions. To this end, a touch sensor has been developed as an input device capable of inputting information such as text, graphics, or the like.

The touch sensor is mounted on a display surface of an image display device such as an electronic organizer, a flat panel display device including a liquid crystal display (LCD) device, a plasma display panel (PDP), an electroluminescence (El) element, or the like, or a cathode ray tube (CRT) to thereby be used to allow a user to select desired information while viewing the image display device.

The touch sensor is classified into a resistive type touch sensor, a capacitive type touch sensor, an electromagnetic type touch sensor, a surface acoustic wave (SAW) type touch sensor, and an infrared type touch sensor. These various types of touch sensors are adapted for electronic products by taking into account of a signal amplification problem, a resolution difference, a level of difficulty of designing and processing technologies, optical characteristics, electrical characteristics, mechanical characteristics, resistant environment, input characteristics, durability, and economic efficiency. Currently, the resistive type touch sensor and the capacitive type touch sensor have been prominently used in a wide range of fields.

These touch sensors typically have a bezel having a color such as black, white, or the like formed on a window glass provided at the outermost portion of a structure of the touch sensor, where the bezel may cover electrode wiring or have a decoration pattern formed thereon.

As a specific example of the touch sensor having the bezel formed thereon according to the prior art, a touch sensor is disclosed in Korean Patent Laid-Open Publication No. 2010-0134226. However, the touch sensor according to the prior art may not prevent an electrical short-circuit when a window substrate is broken, or may not express various design shapes and various colors.

### PRIOR ART DOCUMENT

### Patent Document

(Patent Document 1) Korean Patent Laid-Open Publication No. 2010-0134226

### SUMMARY OF THE INVENTION

The present invention has been made in an effort to provide a touch sensor capable of preventing an electrical short circuit when a window substrate is broken, by bonding a base substrate which is not disassembled upon being broken to the window substrate.

In addition, the present invention has been made in an effort to provide a touch sensor capable of representing a design shape such as a dot/hair line and various colors on a surface of the base substrate by forming a function layer on the surface of the base substrate.

According to a preferred embodiment of the present invention, there is provided a touch sensor, including: a window substrate; a base substrate having one surface formed so as to be bonded to the window substrate and the other surface having a first electrode pattern formed thereon; a bezel formed along an edge of the base substrate; an insulating layer applying the electrode pattern while filling between the bezel and the bezel; and a second electrode pattern formed on the insulating layer.

The touch sensor may further include a function layer formed between the base substrate and the bezel and expressing a color and a material.

The function layer may be formed by a UV coating process and a multi deposition process.

The electrode pattern may be formed on the base substrate so as to have a height of 75 μm or less.

The insulating layer may use at least one of an acryl based, a urethane based, a silicone based, a polyester based, a polyamide based, an epoxy based, a vinyl alkyl ether based, SiOx, and SiNx materials.

A material bonding the window substrate to the base substrate may use a pressure sensitive adhesive (PSA) or an optical clear adhesive (OCA).

According to another preferred embodiment of the present invention, there is provided a touch sensor, including: a window substrate; a base substrate having one surface formed so as to be bonded to the window substrate and the other surface having an electrode pattern formed thereon; and a bezel formed along an edge of the base substrate.

The touch sensor may further include a function layer formed between the base substrate and the bezel and expressing a color and a material.

The electrode pattern may be formed on the function layer as a first electrode pattern and a second electrode pattern.

The function layer may be formed by a UV coating process and a multi deposition process.

The electrode pattern may be formed on the base substrate so as to have a height of 75 μm or less.

A material bonding the window substrate to the base substrate may use a pressure sensitive adhesive (PSA) or an optical clear adhesive (OCA).

According to still another preferred embodiment of the present invention, there is provided a method of manufacturing a touch sensor, the method including: preparing a window substrate; forming a function layer on a surface of a base substrate; forming an electrode pattern and a bezel on the function layer; and bonding the window substrate to one surface of the base substrate.

In the forming of the electrode pattern and the bezel, the electrode pattern may be formed so that a first electrode pattern, an insulating layer, and a second electrode pattern are sequentially formed.

In the forming of the function layer, the function layer may be subjected to a UV coating process and a multi deposition process in order to express a color and a material on the surface of the base substrate.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of a touch sensor according to a preferred embodiment of the present invention;

FIG. 2 is a plan view of the touch sensor shown in FIG. 1;

FIG. 3 is a cross-sectional view of a touch sensor according to a second embodiment of the present invention;

FIG. 4 is a plan view of the an electrode pattern shown in FIG. 3; and

FIGS. 5 to 10 are process views of a touch sensor according to a preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

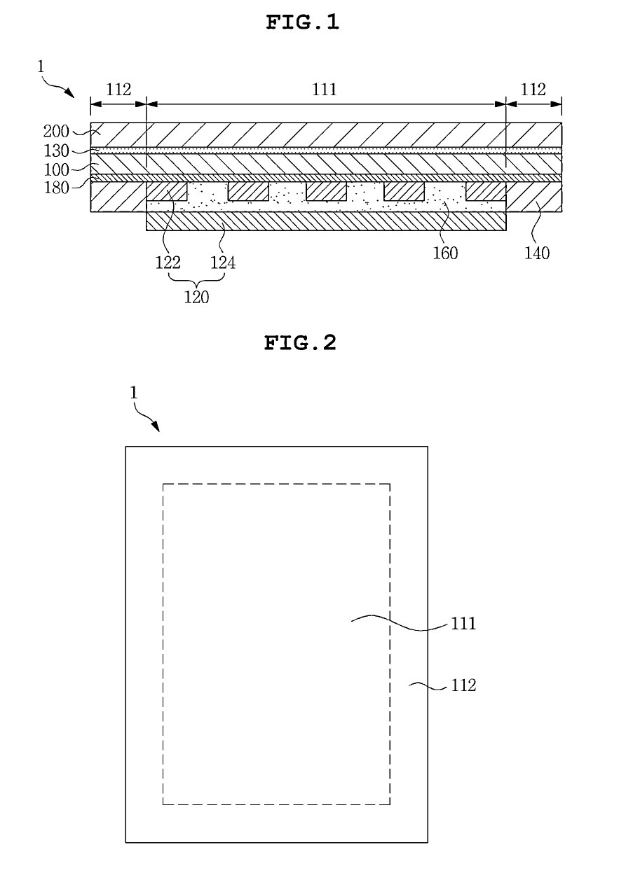

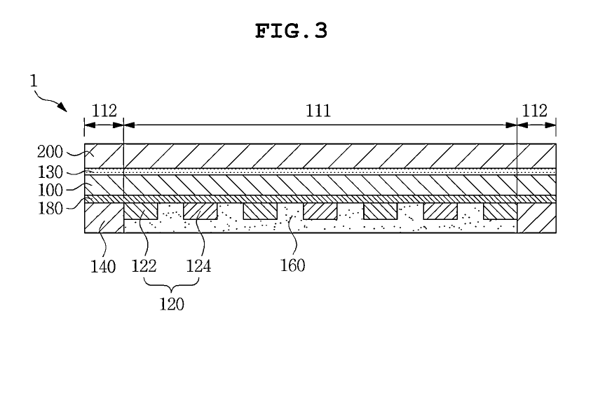

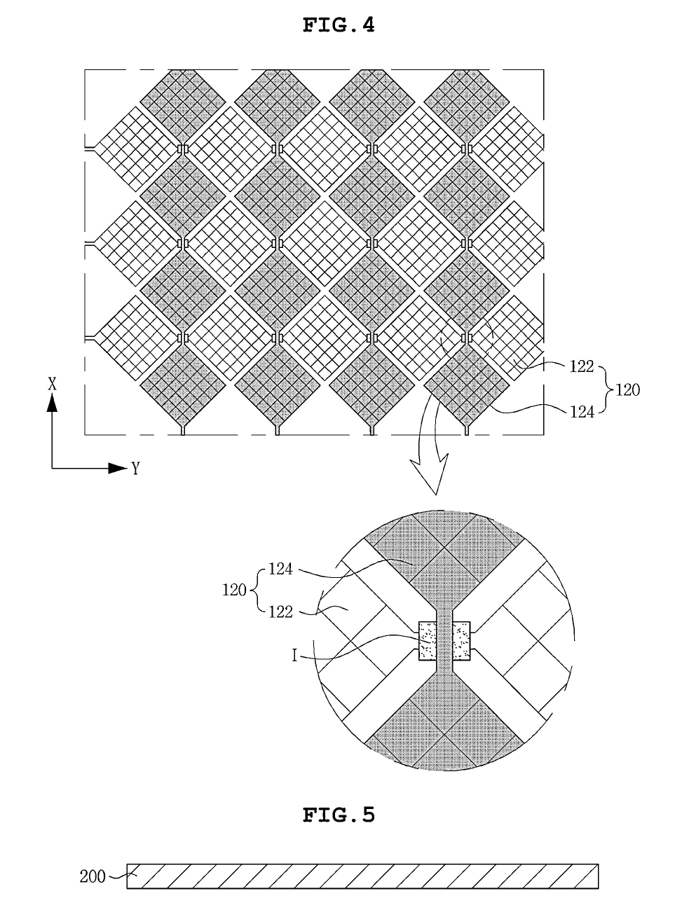

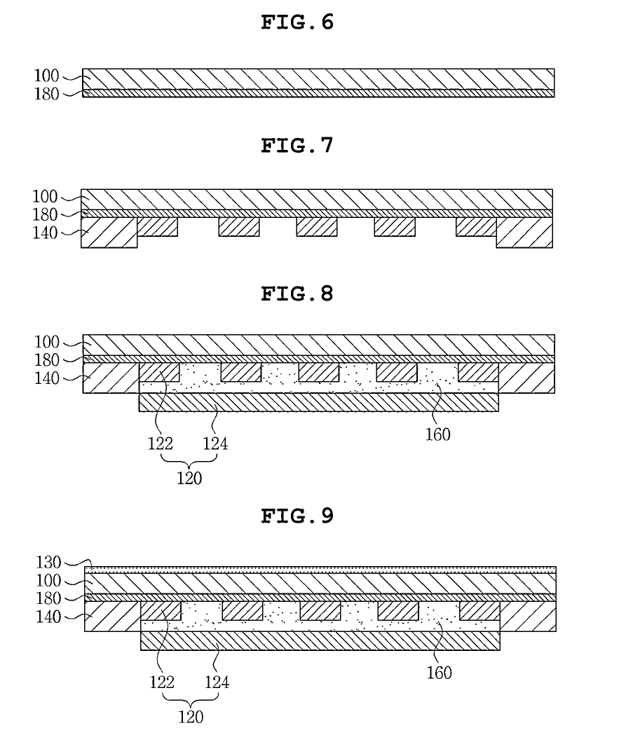

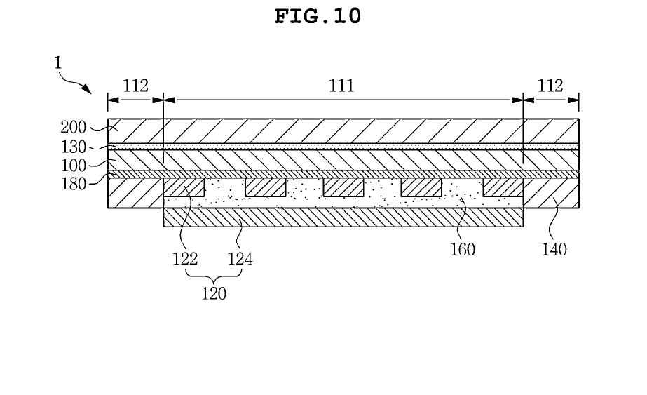

Hereinafter, a preferred embodiment of the present invention will be described in detail with reference to the accompanying drawings. FIG. 1 is a cross-sectional view of a touch sensor according to a preferred embodiment of the present invention, FIG. 2 is a plan view of the touch sensor shown in FIG. 1, FIG. 3 is a cross-sectional view of a touch sensor according to a second embodiment of the present invention, FIG. 4 is a plan view of an electrode pattern shown in FIG. 3, and FIGS. 5 to 7 are process views of a touch sensor according to a preferred embodiment of the present invention.

Referring to FIG. 1, a touch sensor 1 according to a preferred embodiment of the present invention is configured to include a window substrate; a base substrate having one surface formed so as to be bonded to the window substrate and the other surface having a first electrode pattern formed thereon; a bezel formed along an edge of the base substrate; an insulating layer applying the electrode pattern while filling between the bezel and the bezel; and a second electrode pattern formed on the insulating layer.

Referring to FIGS. 1 and 2, the window substrate 200 is formed in a direction in which a touch of user is input from the outermost portion of the touch sensor 1, and serves as a protection layer protecting the touch sensor 1 by using tempered glass having a predetermined strength or more, or the like.

The present invention suggests a process of bonding the base substrate 100 which is not disassembled when being broken to the window substrate 200 in a film form, and forms a function layer 180 on a surface of the base substrate 100, such that production efficiency of a product is improved and a design and color of the product are diversified, thereby making it possible to satisfy sensitivity of the user. The window substrate 200 is formed so as to contact the base substrate 100. In this case, a material of an adhesive 130 adhering the base substrate 100 to the window substrate 200 is not particularly limited, but may use an optical clear adhesive (OCA), a double adhesive tape (DAT), or other transparent insulating materials.

The base substrate 100 is formed so that one surface thereof is bonded to the window substrate 200. One surface of the base substrate 100 contacts the window substrate 200 and the other surface thereof has the function layer 180 formed on the surface thereof. It is advantageous that the base substrate 100 uses the transparent material so that a design shape and color of the function layer 180 are expressed to the outside. This does not intend to limit the material of the base substrate 100.

The base substrate 100 prevents the window substrate 200 from being disassembled to the outside when the window substrate 200 is broken. That is, the user is protected from injury and loss from the disassembly of fragments which are generated by the break of the window substrate 200.

The base substrate 100 serves to provide a region on which the electrode pattern 120 and an electrode wiring (not shown) are formed. Here, the base substrate 100 is partitioned into an active region 111 and an inactive region 112, where the active region 111, which is a portion in which the electrode pattern 120 is formed so as to recognize the touch of the input unit, is provided to the center of the base substrate 100, and the inactive region 112, which is a portion in which the electrode wiring (not shown) extended from the electrode pattern 120 is formed, is provided to the edge of the active region 111. In this case, the base substrate 100 needs to have support force capable of supporting the electrode pattern 120 and the electrode wiring (not shown) and transparency capable of allowing the user to recognize an image provided by the image display device (not shown).

In consideration of the support force and the transparency described above, a material of the base substrate 100 may be made of polyethyleneterephthalate (PET), polycarbonate (PC), polymethylmethacrylate (PMMA), polyethylenenaphthalate (PEN), polyethersulfone (PES), cyclic olefin copolymer (COC), triacetylcellulose (TAC) film, polyvinyl alcohol (PVA) film, polyimide (PI) film, polystyrene (PS), biaxially oriented polystyrene (BOPS; containing K resin), glass or tempered glass, or the like, but is not necessarily limited thereto. The other surface of the base substrate 100 has the function layer 180 formed thereon using a UV coating, a multi coating, or the like.

The function layer 180 is formed on the other surface of the base substrate 100. The function layer 180 is formed on the surface of the base substrate 100 and allows the electrode pattern 120 and the bezel 140 to be formed integrally with the base substrate 100. The function layer 180 expresses various design shapes and colors using a process such as the UV coating, the multi coating, or the like. For example, the function layer 180 may express the design shapes and colors such as a pebble blue (hair line, metallic feeling), a white frost, a black mist (grid type, pearl feeling), or the like.

When the bezel 140 and the electrode pattern 120 are formed on the function layer 180, all of the cost, transmissivity, and yield may be improved. When a sensor is placed on an existing PET, the PET having a thickness of about 100 μm has been used due to a manufacturing process handling. In order to bond the window substrate to the base substrate, a separate adhesive (OCA) having a thickness of about 75 μm is used. That is, in the case in which the PET and the electrode are formed on the window substrate, the thickness of about 175 μm is required in consideration of the process handling, while in the case in which the function layer 180 is integrally formed on the base substrate 100 according to the present invention, the touch sensor may be formed to have the thickness of 75 μm or less, and may be formed to have the thickness of 150 μm even in consideration of the adhesive having the thickness of 75 μm. Therefore, only the thickness small as 25 μm is required as compared to the prior art.

In some cases, the function layer 180 may be used so that the active region 111 and the inactive region 112 are partitioned into different function layers. A main function of the active region 111 performs a function of recognizing a touch operation of the user on the window substrate 200. However, a main function of the inactive region 112 mainly performs a shielding function which allows the electrode wiring (not shown) electrically connected to the electrode pattern 120 not to be visible from the outside. Therefore, the function layer 180 may be formed to be partitioned so as to satisfy the different functions. In addition, the function layer 180 may be formed only at the edge of the base substrate 100. That is, the function layer 180 may be formed only between the base substrate 100 and the bezel 140.

Referring to FIG. 2, the bezel 140 is formed in the inactive region 112 of the base substrate 100. The bezel 140 is disposed along the edge of the base substrate 100 and is formed on the surface of the function layer 180. The bezel 140 serves to cover or decorate one side of the electrode wiring in the inactive region 112 of the window substrate 200. In addition, the bezel 140 may have a decoration pattern such as a manufacturer logo formed thereon, if necessary.

The electrode pattern 120 serve to generate a touch signal which is an input unit, thereby allowing a controller to recognize a touch coordinate. According to the preferred embodiment of the present invention, an electrode pattern formed in an X axis direction of the base substrate 100 is referred to as a first electrode pattern 122, and an electrode pattern formed in an Y axis direction of the base substrate 100 is referred to as a second electrode pattern 124.

Referring to FIG. 1, the first electrode pattern 122 is formed on the function layer 180. The second electrode pattern 124 is formed on an insulating layer 160 described below. The first electrode pattern 122 and the second electrode pattern 124 form bar patterns perpendicular to a bar pattern in one direction on different layers, respectively. The first electrode pattern 122 and the second electrode pattern 124 may perform a touch operation with a touch sensor that is a mutual type by bonding the different layers to each other.

The first electrode pattern 122 and the second electrode pattern 124 may be formed by a plating process or a depositing process using a sputter. It is apparent to those skilled in the art that the first electrode pattern 122 and the second electrode pattern 124 use a metal formed by exposing/developing a silver salt emulsion layer, and various kind of materials capable of forming a mesh pattern using the metal having conductivity may be selected. The first electrode pattern 122 and the second electrode pattern 124 may be formed in all patterns known in the art, such as a diamond shaped pattern, a rectangular pattern, a triangular pattern, a circular pattern, and the like.

The insulating layer 160 is formed between the first electrode pattern 122 and the second electrode pattern 124. The insulating layer 160 is formed so as to apply the first electrode pattern 122. The insulating layer 160 implements an electrical short circuit between the first electrode pattern 122 and the second electrode pattern 124. The insulating layer 160 has the second electrode pattern 124 formed on a surface thereof. As a material of the insulating layer 160, one of an acryl based, a urethane based, a silicone based, a polyester based, a polyamide based, an epoxy based, a vinyl alkyl ether based, SiOx, and SiNx films may be used.

The insulating layer 160 is formed so as to have the same height as the bezel 140. This is to reduce a step of the electrode wiring while horizontally forming the second electrode pattern 124. The insulating layer 160 fills between the bezel 140 and the bezel 140. In this case, the insulating layer 160 is applied up to the height of bezel 140, thereby forming horizontality. The insulating layer 160 is formed of an organic insulating film or inorganic insulating film by a printing method, a chemical vapor deposition (CVD) method, a sputtering method, a spin coating method, a slit die method, a lamination method, or the like.

Referring to FIGS. 3 and 4, in the touch sensor according to the second preferred embodiment of the present invention, a description of the structure and material of the window substrate 200, the base substrate 100, the function layer 180, and the insulating layer 160 which are the same components as those of the first preferred embodiment will be omitted, and a structure of an electrode pattern 120 according to the second preferred embodiment of the present invention will be described in detail.

The touch sensor 1 according to the second preferred embodiment of the present invention is configured to include a window substrate; a base substrate having one surface formed so as to be bonded to the window substrate and the other surface having an electrode pattern formed thereon; and a bezel formed along an edge of the base substrate.

A first electrode pattern 122 in an X axis and a second electrode pattern 124 in a Y axis intersected with the first electrode pattern 122 may be formed on the base substrate 100. In order to form the first electrode pattern 122 and the second electrode pattern 124 to be intersected with each other on one surface of the function layer 180, at a portion in which the first electrode pattern 122 and the second electrode pattern 124 are intersected with each other, an insulating pattern I is formed on any one electrode pattern 120 and the other electrode pattern 120 is electrically connected onto the insulating pattern I, such that an electrical connection between the first electrode pattern 122 and the second electrode pattern 124 which are intersected with each other may be implemented (see FIG. 4). Although an intersection angle of the first electrode pattern 122 and the second electrode pattern 124 which are intersected with each other is shown to be vertical, the intersection angle is not particularly limited, and the first electrode pattern 122 and the second electrode pattern 124 are intersected with each other at an appropriate angle so as to derive coordinates of the X axis and the Y axis in order to extract a coordinate in a two-dimensional plane.

The electrode pattern 120 may be formed in a mesh pattern formed by metal fine lines, where a shape of the mesh pattern includes polygonal shapes such as rectangular shape, a triangular shape, a diamond shape, and the like, but is not limited to a particular shape. The electrode pattern 120 may be formed in the mesh pattern using copper (Cu), aluminum (Al), gold (Au), silver (Ag), titanium (Ti), palladium (Pd), chromium (Cr), nickel (Ni), or a combination thereof.

The electrode pattern 120 may be formed by a dry process, a wet process, or a direct patterning process. Here, the dry process includes a sputtering method, an evaporation method, or the like, the wet process includes a dip coating method, a spin coating method, a roll coating method, a spray coating method, or the like, and the direct patterning process includes a screen printing method, gravure printing method, an inkjet printing method, or the like.

FIGS. 5 to 7 are process views of a touch sensor according to a preferred embodiment of the present invention. Referring to FIGS. 5 to 7, a method of processing a touch sensor 1 according to an preferred embodiment of the present invention includes a) preparing a window substrate; b) forming a function layer on a surface of a base substrate; c) forming an electrode pattern and a bezel on the function layer; and f) bonding the window substrate to one surface of the base substrate.

Referring to FIG. 5, step a) is the preparing of the window substrate. The window substrate 200 is formed in a direction in which a touch of user is input from the outermost portion of the touch sensor 1, and protects the touch sensor 1 using a material such as a tempered glass having a predetermined strength or more, or the like. The window substrate 200 is bonded to one surface of the base substrate 100.

Referring to FIG. 6, the base substrate 100 is prepared in a space separated from the window substrate 200. Step b) is the forming of the function layer 180 on the surface of the base substrate 100. The function layer 180 is formed on the other surface of the base substrate 100 using a UV coating process and a multi deposition process. By performing the UV coating process and the multi deposition process, a color and a material are formed on the surface. For example, a design such as a dot/hair line, or the like is formed. The base substrate 100 prevents the window substrate 200 from being disassembled when the window substrate 200 is broken. The user is protected from injury by fragments disassembled when the window substrate 200 is broken. Further, an electrical short circuit caused by the fragments when the window substrate 200 is broken is prevented.

Referring to FIGS. 7 and 8, step c) is the forming of the electrode pattern 120 and the bezel on the function layer 180. The function layer 180 has the first electrode pattern 122 and the bezel 140 formed on a surface thereof. An insulating layer 160 filling between the bezel 140 and the bezel 140 is formed. That is, the first electrode pattern 122, the insulating layer 160, and the second electrode pattern 124 are sequentially formed. The insulating layer 160 prevents malfunction of the first electrode pattern 122 and the second electrode pattern 124. The insulating layer 160 is formed in a form in which the second electrode pattern 124 is perpendicular to the first electrode pattern 122. The insulating layer 160 is filled between the bezel 140 and the bezel 140 using a printing method, a chemical vapor deposition (CVD) method, a sputtering method, a spin coating method, a slit die method, or the like. The filled insulating layer 160 is formed of an organic insulating film or an inorganic insulating film. In this case, the insulating layer 160 is filled up to a height of the bezel 140.

Referring to FIGS. 9 and 10, step f) is the bonding of the window substrate 200 to one surface of the base substrate 100. The base substrate 100 and the window substrate 200 are bonded to each other. In this case, an adhesive 130 is a transparent material. For example, an optical clear adhesive (OCA), a double adhesive tape (DAT), other transparent insulating materials, or the like is used.

According to the preferred embodiment of the present invention, the base substrate which is not disassembled upon being broken is bonded to the window substrate, such that only the base substrate which is relatively more inexpensive than the window substrate may be discarded when a print error is generated.

In addition, the base substrate which is not disassembled upon being broken is bonded to the window substrate, such that the electrical short circuit may be prevented when the window substrate is broken.

In addition, the base substrate which is not disassembled upon being broken is bonded to the window substrate, such that the touch sensor having the electrode pattern which is not broken when the window substrate is broken may be provided.

In addition, the base substrate which is not disassembled upon being broken is bonded to the window substrate, such that only the base substrate is discarded in the case of the print error, thereby making it possible to prevent the window substrate from being discarded.

In addition, the base substrate which is not disassembled upon being broken is bonded to the window substrate, such that the electrode pattern is not broken when the window substrate is broken, thereby making it possible to provide the touch sensor having improved reliability for the product.

In addition, the touch sensor capable of representing the design shape such as the dot/hair line and various colors may be provided by forming the function layer on the surface of the base substrate.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A touch sensor, comprising:
a window substrate;
a base substrate having one surface formed so as to be bonded to the window substrate and the other surface having a first electrode pattern formed thereon;
a bezel formed along an edge of the base substrate;
an insulating layer applying the electrode pattern while filling between the bezel and the bezel; and
a second electrode pattern formed on the insulating layer.

2. The touch sensor as set forth in claim 1, further comprising a function layer formed between the base substrate and the bezel and expressing a color and a material.

3. The touch sensor as set forth in claim 2, wherein the function layer is formed by a UV coating process and a multi deposition process.

4. The touch sensor as set forth in claim 2, wherein the electrode pattern is formed on the base substrate so as to have a height of 75 μm or less.

5. The touch sensor as set forth in claim 1, wherein the insulating layer uses at least one of an acryl based, a urethane based, a silicone based, a polyester based, a polyamide based, an epoxy based, a vinyl alkyl ether based, SiOx, and SiNx materials.

6. The touch sensor as set forth in claim 1, wherein a material bonding the window substrate to the base substrate uses a pressure sensitive adhesive (PSA) or an optical clear adhesive (OCA).

7. A touch sensor, comprising:
a window substrate;
a base substrate having one surface formed so as to be bonded to the window substrate and the other surface having an electrode pattern formed thereon; and
a bezel formed along an edge of the base substrate.

8. The touch sensor as set forth in claim 7, further comprising a function layer formed between the base substrate and the bezel and expressing a color and a material.

9. The touch sensor as set forth in claim 8, wherein the electrode pattern is formed on the function layer as a first electrode pattern and a second electrode pattern.

10. The touch sensor as set forth in claim 8, wherein the function layer is formed by a UV coating process and a multi deposition process.

11. The touch sensor as set forth in claim 9, wherein the electrode pattern is formed on the base substrate so as to have a height of 75 μm or less.

12. The touch sensor as set forth in claim 7, wherein a material bonding the window substrate to the base substrate uses a pressure sensitive adhesive (PSA) or an optical clear adhesive (OCA).

13. A method of manufacturing a touch sensor, the method comprising:
preparing a window substrate;
forming a function layer on a surface of a base substrate;
forming an electrode pattern and a bezel on the function layer; and
bonding the window substrate to one surface of the base substrate.

14. The method as set forth in claim 13, wherein in the forming of the electrode pattern and the bezel, the electrode pattern is formed so that a first electrode pattern, an insulating layer, and a second electrode pattern are sequentially formed.

15. The method as set forth in claim 13, wherein in the forming of the function layer, the function layer is subjected to a UV coating process and a multi deposition process in order to express a color and a material on the surface of the base substrate.
